(19) United States
(12) Patent Application Publication
(10) Pub. No.: US 2008/0007355 A1
(43) Pub. Date: Jan. 10, 2008

(54) Cr Oscillation Circuit and Electronic Device

(76) Inventor: Takayuki Nakashima, Kyoto (JP)

Correspondence Address: CANTOR COLBURN, LLP, 55 GRIFFIN ROAD SOUTH, BLOOMFIELD, CT, 06002, US

(21) Appl. No.: 11/667,716

(22) PCT Filed: Nov. 15, 2005
(86) PCT No.: PCT/JP05/20946

§ 371 Date: May 14, 2007

(30) Foreign Application Priority Data
Nov. 16, 2004 (JP) 2004-332464

(51) Int. Cl. H03K 3/354; H03K 3/00

(52) U.S. Cl. 331/57; 331/111

(57) ABSTRACT

It is preferable to increase the selection scope of oscillation frequency adjustment means. In a CR oscillation circuit, a first oscillation capacitor and a second oscillation capacitor are arranged in parallel so that a capacity value of the entire CR oscillation circuit can be selected. A plurality of resistors including at least one variable resistor such a fifth trimming resistor are arranged in series, so that the resistance value of the entire CR oscillation circuit can be selected by adjusting the resistance value of the fifth trimming resistor. The minimum value CMIN and the maximum value CMAX which can be selected as a capacitance value of the entire CR oscillation circuit and the minimum value RMIN and the maximum value RMAX which can be selected as a resistance value of the entire CR oscillation circuit are in the relationship as follows: CMIN RMAX≧CMAX RMIN.

### TECHNICAL FIELD

This invention relates to a CR oscillator circuit used for various electronic circuits or the like and an electronic apparatus having said oscillator circuit.

### BACKGROUND TECHNOLOGY

In electronic circuits such as microcomputers mounted on electronic equipment like household electric appliances or video equipment, there are many cases where the oscillator circuit for mainly producing the reference frequency is provided. As examples for this oscillator circuit, known are the crystal/ceramic oscillator circuit using crystal oscillator and ceramic resonator and the CR oscillator circuit using resistors and capacitors.

Normally, the oscillation frequency in a CR oscillator circuit is determined by the characteristics of inverters and each value of capacitors and resistors. In Patent Document 1, a technology is disclosed in which a capacitor is further provided between the input terminal and the ground in the first-stage inverter and the variation in potential of the input terminal in the first-stage inverter is voltage-divided by two capacitors and thereby the occurrence of the voltage higher than the supply voltage or the voltage lower than the ground potential at the input terminal of the first-stage inverter is prevented so as to bring the oscillation frequency close to a theoretical value.

[Patent Document 1]

Japanese Patent Application Laid-Open No. Hei07-131301.

On account of the fact that variation in each element of inverters, capacitors and resistors is large in the conventional CR oscillator circuit, there is a case where the error between the desired oscillation frequency set and the actual oscillation frequency is large. For that reason, there is a case where each value of capacitors and resistors needs to be adjusted after the fabrication. Then it is preferable that the CR oscillator device be provided with a structure that allows the adjustment of oscillation frequencies by various means.

### DISCLOSURE OF THE INVENTION

The present invention has been made in view of these problems and an object thereof is to provide a CR oscillator circuit and an electronic apparatus that broaden the selection margin for means for adjusting the oscillation frequency.

One embodiment of the present invention relates to a CR oscillator circuit. This CR oscillator circuit is characterized in that a plurality of capacitors are provided in parallel and a capacitance value of the CR oscillator circuit as a whole is configured in a selectable manner, a plurality of resistors including at least one variable resistor are provided in series and a resistance value of the CR oscillator circuit as a whole is selectably configured by adjusting a resistance value of the at least one variable resistor, and a relationship is set to CMIN·RMAX≧CMAX·RMIN where CMIN and CMAX are a minimum value and a maximum value, respectively, selectable as a capacitance value of the CR oscillator circuit as a whole and RMIN and RMAX are a minimum value and a maximum value, respectively, selectable as a resistance value of the CR oscillator circuit as a whole.

By setting the above-described relationship in the CR oscillator circuit, the upper bound of a ratio by which the capacitance value of a CR oscillator circuit as a whole is reduced can be lower than the upper bound of a ratio by which the resistance value of a CR oscillator circuit as a whole. In other words, the oscillation frequency can be adjusted to a frequency lower than that obtained before the capacitance value of a CR oscillator circuit as a whole is reduced in a manner that the resistance value of a CR oscillator circuit as a whole is increased at least from RMIN to RMAX maximally even when the capacitance value of a CR oscillator circuit as a whole is reduced maximally from CMAX to CMIN. According to this embodiment, for example, when the oscillation frequency is adjusted low, the adjustment can be accomplished by employing not only a method in which the resistance value is merely increased but also a method in which the capacitance value is reduced and at the same time the resistance value is increased. Hence, the selection margin for means for adjusting the oscillation frequency can be broadened.

Another embodiment of the present invention relates also to a CR oscillator circuit. This CR oscillator circuit comprises: an odd number of inverting circuits connected in series; a trimmable resistor inserted on a path that connects an output end of a final-stage inverting circuit of the odd number of inverting circuits connected in series to an input end of a first-stage inverting circuit of the odd number of inverting circuits connected in series; a first adjustment circuit which adjusts a resistance value of the CR oscillator circuit as a whole by adjusting a resistance value of the resistor by trimming in an increasing direction; a trimmable capacitor for oscillation connected between the input end of the first-stage inverting circuit and an output end of an even-number-stage inverter; and a second adjustment circuit which adjusts a capacitance value of the CR oscillator circuit as a whole by trimming a capacitance value of the capacitor for oscillation, wherein a relationship is set to CMIN·RMAX≧CMAX·RMIN where CMIN and CMAX are a minimum value and a maximum value, respectively, adjustable as a capacitance value of the CR oscillator circuit as a whole and RMIN and RMAX are a minimum value and a maximum value, respectively, adjustable as a resistance value of the CR oscillator circuit as a whole.

The trimmable capacitor for oscillation may be provided in plurality and connected in parallel, and the second adjustment circuit may set the capacitance value, of the CR oscillator circuit as a whole, selectable in a manner that at least one of the plurality of capacitors for oscillation is electrically disconnected from the CR oscillator circuit.

The CR oscillator circuit may further comprise a plurality of capacitors for voltage division which are connected in parallel between the input end of the first-stage inverting circuit and a predetermined fixed potential end, and a relationship may be set to C1:C2=C3:C4 where C1 denotes the total capacitance value of a first group of capacitors in the plurality of capacitors for oscillation, C2 the total capacitance value of a second group of capacitors therein, C3 the total capacitance value of a first group of capacitors in the plurality of capacitors for voltage division and C4 the total capacitance value of a second group of capacitors therein, and when the first group of capacitors in the plurality of capacitors for oscillation is disconnected, the second adjustment circuit may disconnect the first group of capacitors in the plurality of capacitors for voltage division, whereas when the second group of capacitors in the plurality of capacitors for oscillation is disconnected, it may disconnect the second group of capacitors in the plurality of capacitors for voltage division.

Still another embodiment of the present invention relates also to a CR oscillator circuit. This CR oscillator-circuit comprises: an amplifier circuit including an odd number of inverting circuits, of a first stage, an even-number stage and a final stage, connected in series; an inter-path resistor connected on a path that connects an output end of the final-stage inverting circuit to an input end of the first-stage inverting circuit; and a capacitor for oscillation connected on a path that connects the input end of the first-stage inverting circuit to an output end of the even-number-stage inverting circuit, wherein the inter-path resistor is formed by a combination of at least one fixed resistor selected from a first group of resistors and a variable resistor selected from a second group of resistors different from the first group of resistors.

A capacitor, for voltage division, having a predetermined relationship with the capacitor for oscillation may be provided between the input end of the first-stage inverting circuit and a predetermined fixed potential. The capacitor for oscillation and the capacitor for voltage division may be each formed by a plurality of capacitors so that capacitance values of the capacitors are trimmable, and when the total capacitance value of the capacitors for oscillation and the total capacitance value of the capacitors for voltage division before trimming are denoted by CC1 and CC2, respectively, and the total capacitance value of the capacitors for oscillation and the total capacitance value of the capacitors for voltage division after trimming are denoted by CC3 and CC4, respectively, the predetermined relationship may be expressed by CC1:CC2=CC3:CC4.

An upper limit of an adjustable range of resistance values in the variable resistor selected may be approximately equal to or greater than the total value of resistance values in the at least one fixed resistor selected, a resistance value of the inter-path resistor may be made adjustable by selecting at least one fixed resistor from the first group of resistors and selecting a variable resistor from the second group of resistors, and a relationship may be set to CMIN·RMAX≧CMAX·RMIN where RMAX and RMIN are a maximum value and a minimum value, respectively, of adjustable resistance values of the inter-path resistor, and CMAX and CMIN are a maximum value and a minimum value, respectively, of adjustable capacitance values of the capacitor for oscillation.

Still another embodiment of the present invention relates to an electronic apparatus. This electronic apparatus is one in which a voltage control circuit is provided between a bandgap regulator and a CR oscillator circuit, the voltage control circuit inputs a fixed voltage from the bandgap regulator so as to supply a predetermined supply voltage to the CR oscillator circuit, and the voltage control circuit includes: a group of trimming resistors, for reference voltage, which generates a reference voltage by voltage-dividing the fixed voltage; a group of trimming resistors, for detecting voltage, which generates a detecting voltage by voltage-dividing a fed-back supply voltage; a reference voltage comparator which outputs, as the supply voltage, a voltage according to a difference between the reference voltage and the detecting voltage; and a circuit which adjusts each resistance value of the group of trimming resistors for reference voltage and the group of trimming resistors for detecting voltage. This electronic apparatus may be equipped with each of the CR oscillator circuits described in the above embodiments.

### BRIEF DESCRIPTION OF THE DRAWINGS

FIG. 1 shows a structure of an electronic apparatus according to an embodiment.

FIG. 2 is a figure showing an example of the structure of a trimming resistor according to an embodiment.

FIG. 3 shows a structure of a CR oscillator circuit according to an embodiment.

FIG. 4 shows a structure of switching control circuits according to an embodiment.

FIG. 5 is a diagram showing a time change in potential at point a according to an embodiment.

### THE BEST MODE FOR CARRYING OUT THE INVENTION

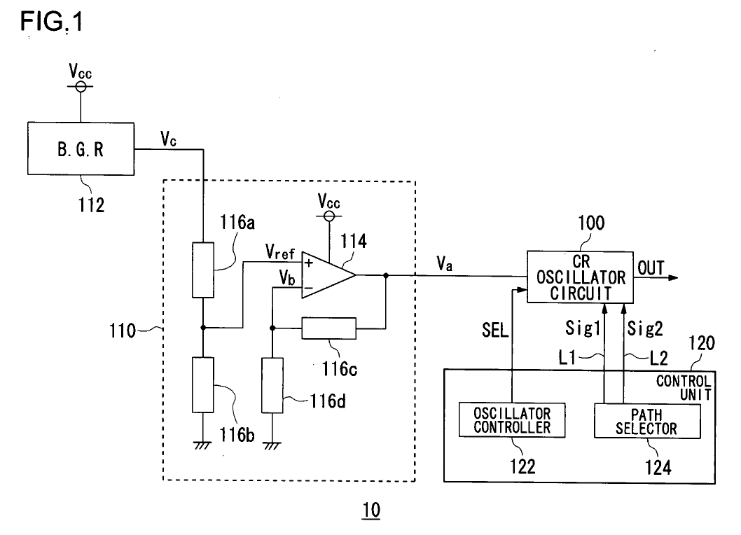

FIG. 1 shows a structure of an electronic apparatus 10 according to an embodiment. The electronic apparatus (electronic device) 10 includes a bandgap regulator 112, a voltage control circuit 110, a CR oscillator circuit (CR oscillation circuit) 100 and a control unit 120. This electronic apparatus 10 is installed in electronic equipment such as household electric appliances or video equipment, and an internal CR oscillator circuit 100 produces a drive signal OUT to drive a LCD (Liquid Crystal Display) panel, not shown.

The bandgap regulator 112 receives the power from a supply voltage Vcc and outputs a voltage of a predetermined fixed voltage Vc, for example, 1.2 V. The voltage control circuit 110 is provided between the bandgap regulator 112 and the CR oscillator circuit 100, inputs the fixed voltage Vc from the bandgap regulator 112 and supplies a predetermined supply voltage Va to the CR oscillator circuit 100. The voltage control circuit 110 includes a group of two pairs of trimming resistors for use with reference voltage for voltage-dividing the fixed voltage Vc and generating a reference voltage Vref, a group of two pairs of trimming resistors for use with detecting voltage for voltage-dividing a fed-back supply voltage Va and generating a detecting voltage Vb, and a reference voltage comparator 114 which outputs a voltage in response to a difference between the reference voltage Vref and the detecting voltage Vb.

The group of trimming resistors for reference voltage includes a first trimming resistor 116a and a second trimming resistor 116b, whereas the group of trimming resistors for detecting voltage includes a third trimming resistor 116c and a fourth trimming resistor 116d. Here, the “first to fourth trimming resistors 116a to 116d” are generically referred to as “trimming resistor 116” as appropriate. Though the detail of the trimming resistor 116 will be described later, the trimming resistor 116 includes a plurality of adjustment resistors therein. And increasing the number of them gradually in the increasing direction can vary the resistance value of the trimming value 116 in the increasing direction.

The bandgap regulator 112, the first trimming resistor 116a and the second trimming resistor 116b are inserted in series between the supply voltage Vcc and a ground. The reference voltage Vref which has been generated as a result of the voltage division by the group of trimming resistors for reference voltage is inputted to a noninverting input terminal of the reference voltage comparator 114. Then the voltage value of the reference voltage Vref can be adjusted by varying the resistance values of the first trimming resistor 116a and the second trimming resistor 116b.

The detecting voltage Vb which has been generated as a result of the voltage division by the group of trimming resistors for detecting voltage is inputted to an inverting input terminal of the reference voltage comparator 114. Then the voltage level of the detecting voltage Vb can be adjusted by varying the resistance values of the first trimming resistor 116a and the second trimming resistor 116b. The reference voltage comparator 114 amplifies a voltage, corresponding to a difference between the reference voltage Vref and the detecting voltage Vb, by a predetermined gain and outputs it as a predetermined supply voltage Va. The gain may be set, as appropriate, according to a circuit. For example, the cases are included where the gain is greater than “1”, the gain is equal to “1” and the gain is less than “1”.

An adjustment operation of the supply voltage Va will be shown hereinbelow. In a manufacturing process, a manufacturer sets values of resistance of the first to fourth trimming resistors 116a to 116d in a manner that the supply voltage Va becomes a targeted voltage. Thereafter, in an examination process, the voltage value of the supply voltage Va is checked to see if the value of the supply voltage Va lies within a predetermined allowable range or not. The predetermined allowable range may be, for example, a range where the upper bound is determined by +5% of the voltage value of the targeted voltage and the lower bound is determined by −5% of the voltage value thereof.

There is a case where the voltage value of the supply voltage Va lies outside the predetermined allowable range due to the reasons why the voltage value of the fixed voltage Vc is varied and so forth. Then the manufacturer varies the resistance values of both the group of trimming resistors for reference voltage and the group of trimming resistors for detecting voltage to adjust the reference voltage Vref and the detecting voltage Vb. As another example, the manufacturer may vary the resistance values of either the group of trimming resistors for reference voltage or the group of trimming resistors for detecting voltage to adjust either one of the reference voltage Vref and the detecting voltage Vb. According to the present embodiment, the variation in the voltage value of the fixed voltage Vc can be absorbed and a stable supply voltage Va can be supplied, so that the CR oscillator circuit can be driven in good condition.

Upon receipt of the supply voltage Va supplied from the voltage control circuit 110, the CR oscillator circuit 100 produces a drive signal OUT of a predetermined oscillation frequency. The oscillation frequency is determined by each value of resistors and capacitors, not shown in FIG. 1, in the CR oscillator circuit 100.

The control unit 120 is a CPU (Central Processing Unit), for instance, and includes a oscillator controller 122 and a path selector 124. The oscillator controller 122 delivers an SEL signal to the CR oscillator circuit 100 and controls the oscillation operation of the CR oscillator circuit 122 based on the SEL signal. More specifically, the oscillator controller 122 instructs the CR oscillator circuit 100 to start the oscillation if the SEL signal is set to the OFF level whereas the oscillator controller 122 instructs it to stop the oscillation if the SEL signal is set to the ON level.

The path selector 124 controls the CR oscillator circuit 100 so that it outputs any one of three kinds of oscillation frequencies. In so doing, the path selector 124 delivers a first control signal Sig1 and a second control signal Sig2, the total of which are constituted by 2 bits, to the CR oscillator circuit 100 via a first signal line L1 and a second signal line L2, respectively.

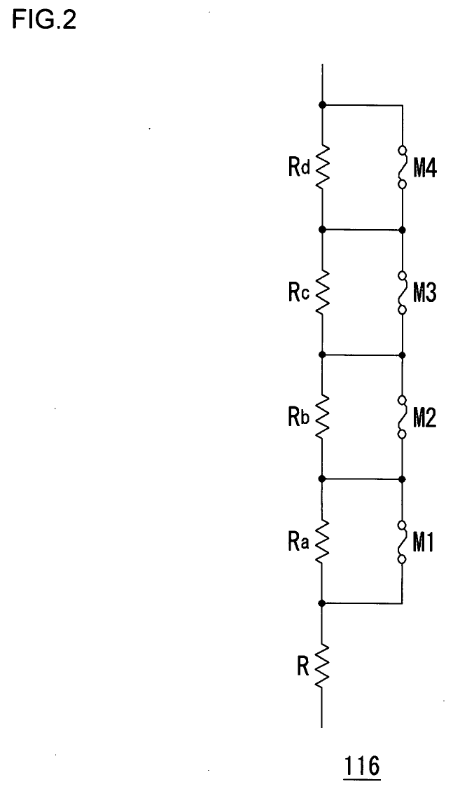

FIG. 2 shows an example of the structure of the trimming resistor 116. The trimming resistor 116 is comprised of a resistor R serving as a reference, first to fourth adjustment resistors Ra to Rd connected in series and first to fourth disconnecting portions for trimming M1 to M4 connected in parallel with the first to fourth adjustment resistors Ra to Rd, respectively. Here, the resistance value of the resistor R is denoted by R and the resistance values of the first to fourth adjustment resistors Ra to Rd are denoted by Ra to Rd, respectively. The resistance values Ra to Rd may be all identical or each different. Since the resistance values of the first to fourth disconnecting portions for trimming M1 to M4 are sufficiently small compared to the resistance values Ra to Rd, the resistance values thereof will be ignored.

The manufacturer can vary the resistance value of the trimming resistor 116 in the range from the resistance value of “R” to the resistance value of “R+Ra+Rb+Rc+Rd” by disconnecting the first to fourth disconnecting portions for trimming M1 to M4 by a laser trimmer or the like. In the present embodiment, however, the resistance value of the resistor R serving as a reference is set to “0” for convenience of explanation. Once the first to fourth disconnecting portions for trimming M1 to M4 are disconnected, the state before the disconnection will not be restored. Hence, the resistance value of the trimming resistor 116 increases every time they are disconnected. Although the number of adjustment resistors shown in the figure is four, the embodiment is not limited thereto.

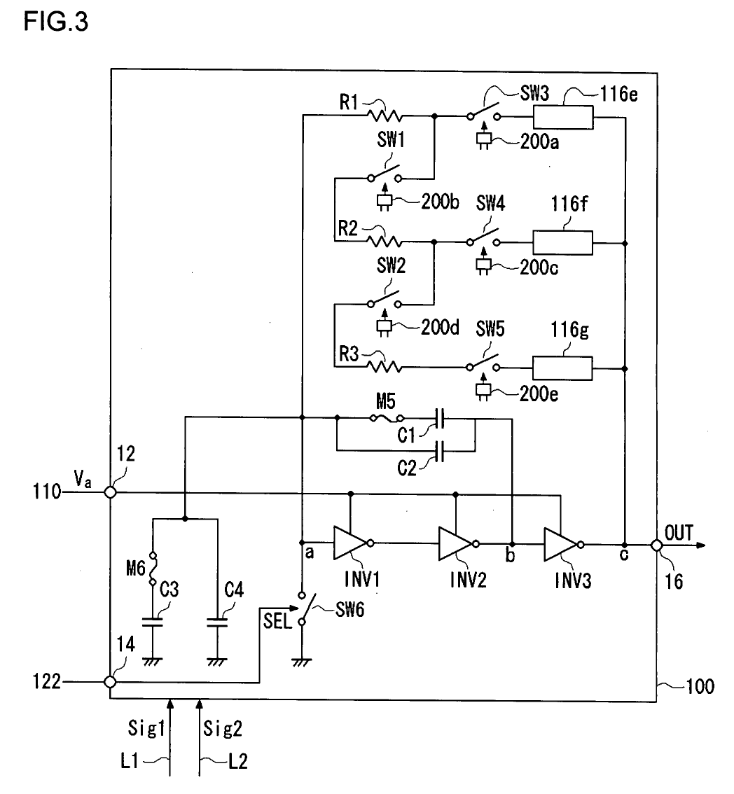

FIG. 3 shows a structure of a CR oscillator circuit 100 according to an embodiment. The CR oscillator circuit 100 includes a first input terminal 12, a second input terminal 14, an output terminal 16, first to third inverting circuits INV1 to INV3, first to sixth switches SW1 to SW6, first to third fixed resistors R1 to R3, fifth to seventh trimming resistors 116e to 116g, first to fourth capacitors C1 to C4 and first to fifth switching control circuit 200a to 200e. The structures of the fifth to seventh trimming resistors 116e to 116g are similar to those of the above-described first to fourth trimming resistors 116a to 116d.

Here, the resistance values of the first to third fixed resistors R1 to R3 are denoted by R1 to R3, respectively, those of the fifth to seventh trimming resistors 116e to 116g by r1 to r3 and the capacitance values of the first to fourth capacitors C1 to C4 by C1 to C4. Here, the resistance value “r1” of the fifth trimming resistor 116e is set greater than the resistance value “R1”, the resistance value “r2” of the sixth trimming resistor 116f is set greater than the resistance value of “R1+R2”, and the resistance value “r3” of the seventh trimming resistor 116g is set greater than the resistance value of “R1+R2+R3”. However, according to the present embodiment, it is assumed for convenience of explanation that the resistance values r1 to r3 are all set greater than the resistance value of “R1+R2+R3”. A relationship of C1:C2=C3:C4 is set among the first to fourth capacitors C1 to C4.

Of the first to third inverting circuits INV1 to INV3 connected in series, the input terminal of the first inverting circuit INV1 is grounded via the sixth switch SW6, and the output terminal of the third inverting circuit INV3 is connected to the output terminal 16. Here, the input terminal of the first inverting circuit INV1 is called the point a, and the output terminal of the third inverting circuit INV3 is called the point c as appropriate. The supply voltage Va from the voltage control circuit 110 is supplied to these first to third inverting circuits INV1 to INV3 via the first input terminal 12.

A SEL signal is inputted from the oscillator controller 122 to the sixth switch SW6 via the second input terminal 14. If the SEL signal is in the OFF level, the sixth switch SW6 will be turned off whereas if the SEL signal is in the ON level, the sixth switch SW6 will be turned on. When the sixth switch SW6 is in the OFF state, the oscillation operation is done by the first to third inverting circuits INV1 to INV3. On the other hand, when the sixth switch SW6 is in the ON state, the oscillation operation by those inverting circuits are not performed. In this case, the first to third switches SW1 to SW3 are so controlled by the path selector 124 that they are set to the OFF state to further reduce the current consumed during the non-operating time.

The fifth trimming resistor 116e, the third switch SW3 and the first fixed resistor R1 are inserted in series on a path that connects an output end of the third inverting circuit INV3 with the input end of the first inverting circuit INV1. The first switch SW1, the second fixed resistor R2, the fourth switch SW4 and the sixth trimming resistor 116f are inserted in series between the point c and a connection point of the first fixed resistor R1 and the third switch SW3. The second switch SW2, the third fixed resistor R3, the fifth switch SW5 and the seventh trimming resistor 116g are inserted in series between the point c and a connection point of the second fixed resistor R2 and the fourth switch SW4.

The first to fifth switches SW1 to SW5 are on-off controlled in accordance with the ON level and the OFF level of output signals from the respective first to fifth switching control circuits 200a to 200e the detail of which will be described later. The two signal lines, which are the first signal line L1 and the second signal line L2, to input these signals must be inputted to the first to fifth switching control circuits 200a to 200e, respectively. However, in order to avoid the complexity in the figure, they are drawn in such a manner as shown in the figure that they enter in the boundary part of the CR oscillator circuit 100. In what is to follow, the first to fifth switching control circuits 200a to 200e will be generically referred to as a switching control circuit 200, as appropriate.

Accordingly, the following three paths (1) to (3) are formed, by the on-off control by the switching control circuit 200, as paths that connect the output end of the third inverting circuit INV3 with the input end of the first inverting circuit INV1.

(1) A path that passes through the fifth trimming resistor 116e and the first fixed resistor R1.

(2) A path that passes through the sixth trimming resistor 116f, the second fixed resistor R2 and the first fixed resistor R1.

(3) A path that passes through the seventh trimming resistor 116g, the third fixed resistor R3, the second fixed resistor R2 and the first fixed resistor R1.

The CR oscillator circuit 100 selects any one of the three paths (1) to (3) to select a value of resistance of the CR oscillator circuit 100 as a whole (hereinafter simply referred to as “total resistance value”). The adjustment of the resistance value of the fifth to seventh trimming resistors 116e to 116g in the increasing direction can achieve the adjustment of the fixed resistance and the combined resistance value of the trimming resistors in the respective paths in the increasing direction. That is, the selection of path or the adjustment of the resistance value of trimming resistors allow the selection of the total resistance value. Here, the minimum value of resistance which can be selected as the total resistance value is denoted by RMIN and the maximum value of resistance by RMAX. In the case of the present embodiment, RMIN corresponds to the resistance value of “R1” and RMAX the resistance value of “R1+R2+R3+r3”.

The first capacitor C1 and the second capacitor C2 which are capacitors for oscillation are connected in parallel between the input end of the first inverting circuit INV1 and the output end of the second inverting circuit INV2. Here, the output end of the second inverting circuit INV2 is called the point b, as appropriate. The fifth disconnecting portion for trimming M5 is provided in the vicinity of the first capacitor C1. The third capacitor C3 and the fourth capacitor C4, which are capacitors for voltage division, are connected in parallel between the input end of the first inverting circuit INV1 and an end of a predetermined fixed potential (for example, the ground). Similarly to the first capacitor C1, the sixth disconnecting portion for trimming M6 is provided in the vicinity of the third capacitor C3.

By disconnecting both the fifth disconnecting portion for trimming M5 and the sixth disconnecting portion for trimming M6, the manufacturer electrically shuts off the first capacitor C1 and the third capacitor C3 from the CR oscillator circuit 100. Thereby, the capacitance value of the CR oscillator circuit 100 as a whole (hereinafter simply referred to as “total capacitance value”) can be selected. Here, the minimum capacitance value which can be selected as the total capacitance value is denoted by CMIN and the maximum capacitance value by CMAX. In the case of the present embodiment, CMIN corresponds to the capacitance value of “C2+C4” and CMAX the capacitance value of “C1+C2+C3+C4”.

As described above, the relationship of C1:C2=C3:C4 is set among the first to fourth capacitors C1 to C4. Hence, a relationship
(C1+C2):(C3+C4)=C2:C4
holds among the total value of capacitances for oscillation before trimming, namely, “C1+C2”, the total value of capacitances for voltage division, namely, “C3+C4”, the total value of capacitances for oscillation after trimming, namely, “C2” and the total value of capacitances for voltage division, namely, “C4”.

Here, the oscillation frequency F is determined by the characteristics of the first to third inverting circuits INV1 to INV3 and the capacitance values of the first to fourth capacitors C1 to C4, the resistance values of the first to third resistors R1 to R3 and the resistance values of the fifth to seventh trimming resistors 116e to 116g, and it is expressed by the following equation.

$$F = - \frac{1}{\begin{matrix}C R \{ {I}_{n} ( \frac{{V}_{TH}}{{V}_{TH} + \frac{C 3 + C 4}{C} Va} ) + \\ {I}_{n} ( \frac{{V}_{TH} - Va}{{V}_{TH} - Va - \frac{C 3 + C 4}{C} Va} ) \}\end{matrix}} \qquad ( Eq . 1 )$$

where the total capacitance value C is C=C1+C2+C3+C4 and R is the combined resistance value of resistors inserted in any of paths selected by the path selector 124, for instance, “R1+R2+R3+r3”. According to this equation, shutting off the capacitor results in the increase of the oscillation frequency F, and the increase in resistance value reduces the oscillation frequency F.

The following relationship is set among RMIN, RMAX, CMIN and CMAX in the CR oscillator circuit 100 according to the present embodiment.
CMIN·RMAX≧CMAX·RMIN (A)

If the resistors and the capacitors that satisfy this Equation A are provided in the CR oscillator circuit 100, the upper bound of the ratio to reduce the total capacitance value of the CR oscillator circuit 100 can be set lower than the upper bound of total capacitance value to raise the total capacitance value. That is, even when a capacitor is shut off so as to reduce maximally the total capacitance value from CMAX to CMIN, the frequency can be adjusted to a frequency which is lower than that before shutting off the capacitor by at least increasing maximally the total resistance value from RMIN to RMAX.

For example, assume that each of the four capacitors has the same capacitance value of 4 pF and each of the resistance values R1 to R3 has the same value of 8 kΩ. Since the upper bound of the variable range of the resistance values r1 to r3 is set to a value greater than the resistance value of “R1+R2+R3” as described above, it is assumed to be 32 kΩ. In this case, CMIN=8 pF, CMAX=16 pF, RMIN=8 kΩ and RMAX=56 kΩ, so that the equation (A) is satisfied. When the first capacitor C1 and the third capacitor C3 are shut off and then the total capacitance value is varied from 16 pF to 8 pF, the oscillation frequency F is doubled. However, since the resistance value can be adjusted to more than the double of RMIN=8 kΩ as the total resistance value, the oscillation frequency F can be adjusted to a value lower than the oscillation frequency before being shut off.

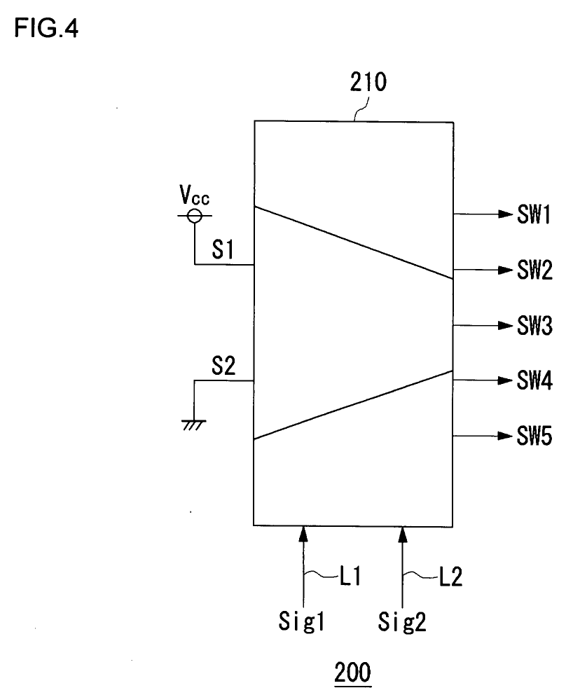

FIG. 4 shows a structure of the switching control circuit 200. Here, the structures of the first to fifth switching control circuits 200a to 200e are shown by a single figure. The internal structures of the first to fifth switching control circuits 200a to 200e are each designed separately, and they select a required input signal, based on the first control signal Sig1 and the second control signal Sig2, from two signals described later.

This switching control circuit 200 has a selector 210. Based on the first control signal Sig1 and the second control signal Sig2 supplied via the first signal line L1 and the second signal line L2, this selector 210 selects either a first input signal S1 of H level supplied from the supply voltage Vcc or a second input signal S2 supplied from the ground and then delivers it to the first to fifth switches SW1 to SW5, respectively.

More specifically, when the first control signal Sig1 of H level and the second control signal Sig2 of H level are delivered by the path selector 124 of FIG. 1, namely, when the path (1) is selected, the selector 210 delivers a signal of ON level to the third switch SW3 and delivers a signal of OFF level to the other switches. On the other hand, when the first control signal Sig1 of H level and the second control signal Sig2 of L level are delivered, namely, when the path (2) is selected, the selector 210 delivers a signal of ON level to the first switch SW1 and the fourth switch SW4 and delivers a signal of OFF level to the other switches. Further, when the first control signal Sig1 of L level and the second control signal Sig2 of H level are delivered, namely, when the path (3) is selected, the selector 210 delivers a signal of ON level to the first switch SW1, the second switch SW2 and the fifth switch SW5 and delivers a signal of OFF level to the other switches. When the first control signal Sig1 of L level and the second control signal Sig2 of L level are delivered by the path selector 124 of FIG. 1, namely, when the sixth switch SW is turned on and the oscillation operation is not performed, the selector 210 delivers a signal of ON level to the third to fifth switches SW3 to SW5 and delivers a signal of OFF level to the other switches. As a result, the consumption current can be reduced.

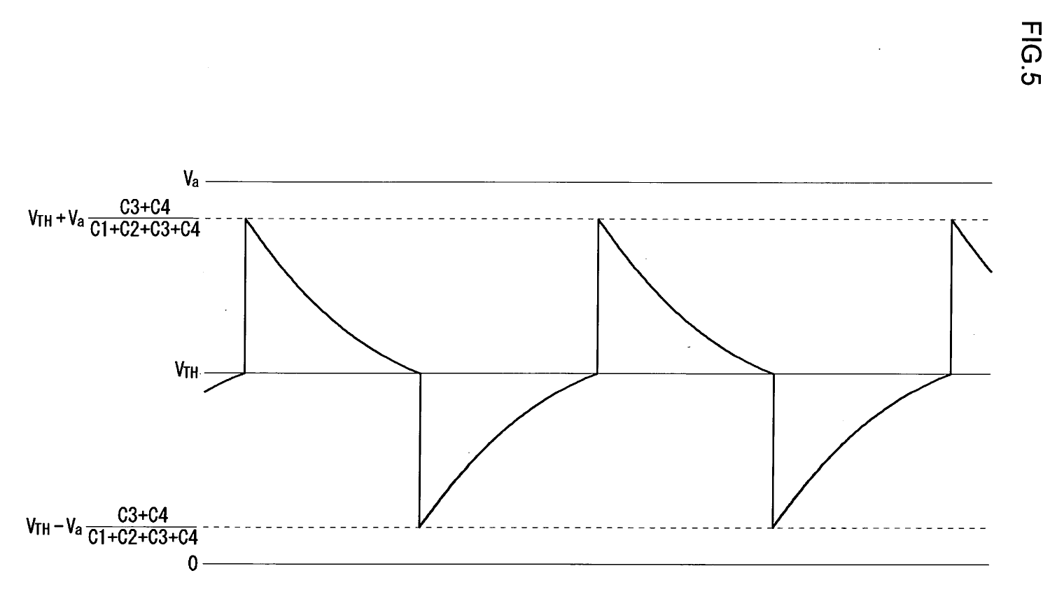

FIG. 5 shows the time change in potential at the point a. A description will be given hereinbelow of the time change in potential at the point a with reference to FIG. 3 and FIG. 5. When the potential at the point a is of L level, namely, when the potential at the point c is of H level, the first to fourth capacitors C1 to C4 are charged through resistors selected. As the first to fourth capacitors C are getting charged, the potential at the point a increases and exceeds a threshold voltage V_{TH} of the first inverting circuit INV1. Then the potential at the point b becomes H level. However, since the voltage is divided by the first to fourth capacitors C1 to C4, the potential at the point a becomes “VTH+Va×(C3+C4)/(C1+C2+C3+C4)”.

Here, when the potential at the point b becomes H level, the potential at the point c becomes L level and the first to fourth capacitors C1 to C4 are discharged via the resistors selected. As the first to fourth capacitors C1 to C4 are getting discharged, the potential at the point a declines below the threshold voltage V_{TH} of the first inverting circuit INV1. Then the potential at the point a becomes “V_{TH}−Va×(C3+C4)/(C1+C2+C3+C4)” because the potential at the point b becomes L level but the voltage is divided by the first to fourth capacitors C1 to C4. When the potential at the point b becomes L level, the potential at the point c becomes H level. From here on, this operation is repeated, so that the CR oscillator circuit 100 oscillates. Thereby, the occurrence of voltage greater than the supply voltage or lower that the ground potential can be prevented at the point a.

As described above, the relationship of C1:C2=C3:C4 is set among the respective capacitors. Furthermore, since the third capacitor C3 is also shut off at the time of shutting of the first capacitor C1, the value calculated by “(C3+C4)/(C1+C2+C3+C4)” before the shutting off is equal to the value calculated by “C4/(C2+C4)” after the shutting off, so that the characteristics remains unchanged. Thus, the peak value of oscillation waveform also remains the unchanged. As a result of thereof, variation range of potential occurring at the point a can be kept constant.

Using FIG. 3, an adjustment operation of the CR oscillator circuit according to the present embodiment to adjust the oscillation frequency F will be explained. At the time of the initial state it is assumed that the first capacitor C1 and the third capacitor C3 are not shut off, the both ends of the fifth to seventh trimming resistors 116e to 116g are short-circuited and the resistance values thereof are set to “0”. Then the CR oscillator circuit 100 can select from among three kinds of oscillation frequencies F, namely, the frequency when the total resistance value is “R1”, the frequency when it is “R1+R2” and the frequency when it is “R1+R2+R3” and can output the selected one.

In the examination process, the manufacturer checks to see if each of the three kinds of oscillation frequencies F lies within a predetermined allowable range or not. Three kinds of oscillation frequencies F may each lie outside each predetermined allowable range due to the reason why the capacitance values of capacitors and the resistance values of resistors are varied. When this happens, the manufacturer adjusts the oscillation frequencies F to desired values in a manner that the resistance values of the fifth to seventh trimming resistors 116e to 116g are adjusted, the capacitors are shut off or both operations are combined. An example of a method for adjusting the oscillation frequency F will be explained hereinbelow.

When the oscillation frequency F is higher than the upper bound of frequency in the allowable range and therefore the oscillation frequency F is to be set low, the manufacturer performs the following adjustment operations.

(i) The resistance value of the fifth trimming resistor 116e is set larger and the value of resistance for oscillation, or “R1+r1”, is set larger.

(ii) The resistance value of the sixth trimming resistor 116f is set larger and the value of resistance for oscillation, or “R1+R2+r2”, is set larger.

(iii) The resistance value of the seventh trimming resistor 116g is set larger and the value of resistance for oscillation, or “R1+R2+R3+r3”, is set larger.

On the other hand, when the oscillation frequency F is lower than the lower bound of frequency in the allowable range and the oscillation frequency F is to be set higher, the manufacturer performs:

(iv) The first capacitor C1 and the third capacitor C3 are shut off from the CR oscillator circuit 100 and the total capacitance value of “C1+C2+C3+C4” is set smaller.

As described above, the CR oscillator circuit 100 satisfies the above relationship (A). The manufacturer can adjust to set the oscillation frequency F low by using not only a method of reducing the total capacitance vale but also a method of increasing the total resistance value. That is, the manufacturer can adjust to set the oscillation frequency F low by implementing not only the means of (i), (ii) or (iii), in which the resistance value is merely increased, but also the means of (iv) together with the means of (i), (ii) or (iii). As a result, the selection margin for a method for adjusting the oscillation frequency F can be broadened.

Furthermore, according to the present embodiments, when a desired oscillation frequency F is to be set, the total resistance value R is adjusted and at the same time a means is employed in which, for example, the first capacitor C1 and the third capacitor C3 are shut off, in place of employing a method in which the total resistance value R only is adjusted. Thus, the charge-discharge current can be reduced and low power consumption is ensured. The number of the capacitors for oscillation and the number of capacitors for voltage division, whose areas occupied in a semiconductor integrated circuit are large, are each set to two, which represents the minimum structure in the structure to achieve the selection. Thus the reduction in circuit scale as a whole can be attained.

The correspondence in structure between the present invention and the embodiments are exemplified here. A “first adjustment circuit” corresponds to the first to fourth disconnecting portions for trimming M1 to M4, and a “second adjustment circuit” corresponds to the fifth disconnecting portion for trimming M5 and the sixth disconnecting portion for trimming M6. A “first group of resistors” correspond to the first fixed resistor R1 to the third fixed resistor R3, and a “second group of resistors” correspond to the fifth trimming resistor 116e to the seventh trimming resistor 116g. An “inter-path resistor” corresponds to a combination of at least one of the first fixed resistor R1 to the third fixed resistor R3 and any one of the fifth trimming resistor 116e to the seventh trimming resistor 116g.

The present invention has been described based on the embodiments. These embodiments are merely exemplary, and various modifications to the combination of each component and process thereof are possible. It is understood by those skilled in the art that such modifications are also within the scope of the present invention. Such modification will follow.

In the present embodiment, two capacitor are provided as the capacitors for oscillation and another two as the capacitors for voltage division, but are not limited thereto and it suffices if a plurality of them are provided. Then in the capacitance values of those capacitors, when the total capacitance value of the first group of capacitors is denoted by C1 and the total capacitance value of the second group of capacitors is C2 among a plurality of capacitors for oscillation and the total capacitance value of the first group of capacitors is C3 and the total capacitance value of the second group of capacitors is C4 among a plurality of capacitors for voltage division, a relationship among those is set to
C1:C2=C3:C4.

With this, when the first group of capacitors among a plurality of capacitors for oscillation is disconnected by the disconnecting portions for trimming, the manufacturer disconnects the first group of capacitors among a plurality of capacitors for voltage division. On the other hand, when the second group of capacitors among the plurality of capacitors for oscillation is disconnected thereby, the manufacturer disconnects the second group of capacitors among the plurality of capacitors for voltage division.

According to this, similar to the present embodiments, the occurrence of voltage higher than the supply voltage or lower than the ground potential at the point a of FIG. 3 can be suppressed and at the same time the variation range of potential generated at the point a can be kept constant even after the disconnection.

The CR oscillator circuit 100 according to the present embodiments has three paths. However, the number of paths is not limited thereto. That is, the CR oscillator circuit 100 may have one or two path, or may have four or more paths as well.

In the present embodiments, two inverting circuits are provided between the point a and the point b. However, they are not limited thereto and it is satisfactory as long as an even number of them are provided. In the present embodiments, three inverting circuits are provided. However they are not limited thereto and it is satisfactory as long as an odd number of them are provided.

In the present embodiments, the oscillation operation is controlled by turning on and off the sixth switch SW6. As a modification thereto, a logic gate in place of the first inverting circuit INV1 may be provided in FIG. 3. In this case, the SEL signal from the oscillation control circuit 122 may be inputted to the logic gate so as to control the oscillation operation of the CR oscillator circuit 100 according to the ON level and OFF level of the SEL signal. As the above-described manufacture, there may be a case where the manufacturer is one who manufactures a semiconductor device having the CR oscillator circuit and a case where the manufacturer is one who manufacturers an electronic apparatus using said circuit. In the latter case, the manufacturer of electronic apparatus may be able to electrically control the selection of ON level and OFF level of the SEL signal, from an external source.

### INDUSTRIAL APPLICABILITY

The present invention can be used for a CR oscillator circuit mounted on electronic equipment such as household electric appliances or video equipment.

1. A CR oscillator circuit characterized in that a plurality of capacitors are provided in parallel and a capacitance value of said CR oscillator circuit as a whole is configured in a selectable manner,
a plurality of resistors including at least one variable resistor are provided in series and a resistance value of said CR oscillator circuit as a whole is selectably configured by adjusting a resistance value of the at least one variable resistor, and
a relationship is set to
CMIN·RMAX≧CMAX·RMIN
where CMIN and CMAX are a minimum value and a maximum value, respectively, selectable as a capacitance value of said CR oscillator circuit as a whole and RMIN and RMAX are a minimum value and a maximum value, respectively, selectable as a resistance value of said CR oscillator circuit as a whole.

2. A CR oscillator circuit, comprising:
an odd number of inverting circuits connected in series;
a trimmable resistor inserted on a path that connects an output end of a final-stage inverting circuit of said odd number of inverting circuits connected in series to an input end of a first-stage inverting circuit of said odd number of inverting circuits connected in series;
a first adjustment circuit which adjusts a resistance value of said CR oscillator circuit as a whole by adjusting a resistance value of the resistor by trimming in an increasing direction;
a trimmable capacitor for oscillation connected between the input end of the first-stage inverting circuit and an output end of an even-number-stage inverter; and
a second adjustment circuit which adjusts a capacitance value of said CR oscillator circuit as a whole by trimming a capacitance value of said capacitor for oscillation,
wherein a relationship is set to
CMIN·RMAX≧CMAX·RMIN
where CMIN and CMAX are a minimum value and a maximum value, respectively, adjustable as a capacitance value of said CR oscillator circuit as a whole and RMIN and RMAX are a minimum value and a maximum value, respectively, adjustable as a resistance value of said CR oscillator circuit as a whole.

3. A CR oscillator circuit according to claim 2, wherein said trimmable capacitor for oscillation is provided in plurality and connected in parallel, and
wherein said second adjustment circuit sets the capacitance value, of said CR oscillator circuit as a whole, selectable in a manner that at least one of the plurality of capacitors for oscillation is electrically disconnected from said CR oscillator circuit.

4. A CR oscillator circuit according to claim 3, further comprising a plurality of capacitors for voltage division which are connected in parallel between the input end of the first-stage inverting circuit and a predetermined fixed potential end,
wherein a relationship is set to
C1:C2=C3:C4
where C1 denotes the total capacitance value of a first group of capacitors in the plurality of capacitors for oscillation, C2 the total capacitance value of a second group of capacitors therein, C3 the total capacitance value of a first group of capacitors in the plurality of capacitors for voltage division and C4 the total capacitance value of a second group of capacitors therein, and
wherein when the first group of capacitors in the plurality of capacitors for oscillation is disconnected, said second adjustment circuit disconnects the first group of capacitors in the plurality of capacitors for voltage division, whereas when the second group of capacitors in the plurality of capacitors for oscillation is disconnected, it disconnects the second group of capacitors in the plurality of capacitors for voltage division.

5. A CR oscillator circuit, comprising:
an amplifier circuit including an odd number of inverting circuits, of a first stage, an even-number stage and a final stage, connected in series;
an inter-path resistor connected on a path that connects an output end of the final-stage inverting circuit to an input end of the first-stage inverting circuit; and
a capacitor for oscillation connected on a path that connects the input end of the first-stage inverting circuit to an output end of the even-number-stage inverting circuit,
wherein said inter-path resistor is formed by a combination of at least one fixed resistor selected from a first group of resistors and a variable resistor selected from a second group of resistors different from the first group of resistors.

6. A CR oscillator circuit according to claim 5, wherein a capacitor, for voltage division, having a predetermined relationship with the capacitor for oscillation is provided between the input end of the first-stage inverting circuit and a predetermined fixed potential.

7. A CR oscillator circuit according to claim 6, wherein the capacitor for oscillation and the capacitor for voltage division are each formed by a plurality of capacitors so that capacitance values of the capacitors are trimmable, and
wherein when the total capacitance value of the capacitors for oscillation and the total capacitance value of the capacitors for voltage division before trimming are denoted by CC1 and CC2, respectively, and the total capacitance value of the capacitors for oscillation and the total capacitance value of the capacitors for voltage division after trimming are denoted by CC3 and CC4, respectively, the predetermined relationship is expressed by
CC1:CC2=CC3:CC4.

8. A CR oscillator circuit according to claim 7, wherein an upper limit of an adjustable range of resistance values in the variable resistor selected is approximately equal to or greater than the total value of resistance values in the at least one fixed resistor selected, a resistance value of said inter-path resistor is made adjustable by selecting at least one fixed resistor from the first group of resistors and selecting a variable resistor from the second group of resistors, and a relationship is set to
CMIN·RMAX≧CMAX·RMIN
where RMAX and RMIN are a maximum value and a minimum value, respectively, of adjustable resistance values of said inter-path resistor, and CMAX and CMIN are a maximum value and a minimum value, respectively, of adjustable capacitance values of the capacitor for oscillation.

9. An electronic apparatus in which a voltage control circuit is provided between a bandgap regulator and a CR oscillator circuit,
the voltage control circuit inputting a fixed voltage from the bandgap regulator so as to supply a predetermined supply voltage to the CR oscillator circuit,
the voltage control circuit including:
a group of trimming resistors, for reference voltage, which generates a reference voltage by voltage-dividing the fixed voltage;
a group of trimming resistors, for detecting voltage, which generates a detecting voltage by voltage-dividing a fed-back supply voltage;
a reference voltage comparator which outputs, as the supply voltage, a voltage according to a difference between the reference voltage and the detecting voltage; and
a circuit which adjusts each resistance value of the group of trimming resistors for reference voltage and the group of trimming resistors for detecting voltage.

10. An electronic apparatus according to claim 9, wherein the CR oscillator circuit is a CR oscillator circuit characterized in that a plurality of capacitors are provided in parallel and a capacitance value of said CR oscillator circuit as a whole is configured in a selectable manner,
a plurality of resistors including at least one variable resistor are provided in series and a resistance value of said CR oscillator circuit as a whole is selectably configured by adjusting a resistance value of the at least one variable resistor, and
a relationship is set to
CMIN·RMAX≧CMAX·RMIN
where CMIN and CMAX are a minimum value and a maximum value, respectively, selectable as a capacitance value of said CR oscillator circuit as a whole and RMIN and RMAX are a minimum value and a maximum value, respectively, selectable as a resistance value of said CR oscillator circuit as a whole.

11. An electronic apparatus according to claim 9, wherein the CR oscillator circuit is a CR oscillator circuit, comprising:
an odd number of inverting circuits connected in series;
a trimmable resistor inserted on a path that connects an output end of a final-stage inverting circuit of said odd number of inverting circuits connected in series to an input end of a first-stage inverting circuit of said odd number of inverting circuits connected in series;
a first adjustment circuit which adjusts a resistance value of said CR oscillator circuit as a whole by adjusting a resistance value of the resistor by trimming in an increasing direction;
a trimmable capacitor for oscillation connected between the input end of the first-stage inverting circuit and an output end of an even-number-stage inverter; and
a second adjustment circuit which adjusts a capacitance value of said CR oscillator circuit as a whole by trimming a capacitance value of said capacitor for oscillation,
wherein a relationship is set to
CMIN·RMAX≧CMAX·RMIN
where CMIN and CMAX are a minimum value and a maximum value, respectively, adjustable as a capacitance value of said CR oscillator circuit as a whole and RMIN and RMAX are a minimum value and a maximum value, respectively, adjustable as a resistance value of said CR oscillator circuit as a whole.

12. An electronic apparatus according to claim 9, wherein the CR oscillator circuit is a CR oscillator circuit, comprising:
an amplifier circuit including an odd number of inverting circuits, of a first stage, an even-number stage and a final stage, connected in series;
an inter-path resistor connected on a path that connects an output end of the final-stage inverting circuit to an input end of the first-stage inverting circuit; and
a capacitor for oscillation connected on a path that connects the input end of the first-stage inverting circuit to an output end of the even-number-stage inverting circuit,
wherein said inter-path resistor is formed by a combination of at least one fixed resistor selected from a first group of resistors and a variable resistor selected from a second group of resistors different from the first group of resistors.
